(19) United States
(12) Patent Application Publication
(10) Pub. No.: US 2017/0229292 A1
(43) Pub. Date: Aug. 10, 2017

(54) PLASMA CHEMICAL VAPOR DEPOSITION DEVICE

(71) Applicant: TOYOTA JIDOSHA KABUSHIKI KAISHA, Toyota-shi (JP)

(72) Inventors: Yoji SATO, Kasugai-shi (JP); Takayasu SATO, Takahama-shi (JP); Kazutaka TACHIBANA, Nagoya-shi (JP); Hiromichi NAKATA, Toyota-shi (JP)

(73) Assignee: TOYOTA JIDOSHA KABUSHIKI KAISHA, Toyota-shi (JP)

(21) Appl. No.: 15/422,112

(22) Filed: Feb. 1, 2017

(30) Foreign Application Priority Data
Feb. 9, 2016 (JP) 2016-022821

(51) Int. Cl. H01J 37/32

(52) U.S. Cl. CPC H01J 37/32853; H01J 37/32201; H01J 2237/3321

(57) ABSTRACT

A plasma chemical vapor deposition device includes an adhesion suppressing sheet suppressing a processing gas from adhering to an inner wall of a reactor. The adhesion suppressing sheet is arranged between a placement position of a workpiece and the inner wall of the reactor. The adhesion suppressing sheet is a fabric that includes first fiber bundles and second fiber bundles that extend in directions different from each other. In the first fiber bundles, front side portions and rear side portions are alternately arranged in a first direction. In the second fiber bundles, front side portions and rear side portions are alternately arranged in a second direction.

### INCORPORATION BY REFERENCE

The disclosure of Japanese Patent Application No. 2016-022821 filed on Feb. 9, 2016 including the specification, drawings and abstract is incorporated herein by reference in its entirety.

### BACKGROUND

1. Technical Field

The present disclosure relates to a plasma chemical vapor deposition device.

2. Description of Related Art

In a plasma chemical vapor deposition device (hereinafter referred to as a “PCVD device”), processing gases are converted into plasma and decomposed in the vicinity of a workpiece placed in a reactor, and a film is formed on the workpiece. When a film is formed on the workpiece in this manner, among processing gases decomposed by plasmatization, some of the gases that do not adhere to the workpiece adhere to an inner wall of the reactor. When an adhesive substance based on such processing gases is deposited on the inner wall of the reactor, a force with which the inner wall is deformed is applied to the inner wall by the adhesive substance. However, since the inner wall of the reactor has high rigidity, the inner wall is not deformed even when a force is applied by the deposited adhesive substance. Therefore, the internal stress that is a force accumulated inside the adhesive substance is likely to increase. Accordingly, when the internal stress of the adhesive substance increases to an extent that continuous adhesion is not possible with an adhesion force applied to the inner wall by the adhesive substance, the adhesive substance is exfoliated from the inner wall. In this case, the adhesive substance exfoliated from the inner wall of the reactor may be scattered as flakes inside the reactor, and the flakes may adhere to the workpiece placed in the reactor.

Therefore, a method in which an adhesion suppressing sheet described in, for example, Japanese Patent Application Publication No. H4-289159 (JP H4-289159 A), is arranged between a placement position of a workpiece in a reactor and an inner wall of the reactor, and thus deposition of an adhesive substance on the inner wall is suppressed and scattering of flakes in the reactor is suppressed is known.

The adhesion suppressing sheet described in JP H4-289159 A is formed of a thin aluminum plate. As shown in FIG. 10, in an adhesion suppressing sheet 100, a plurality of unevennesses are provided and thus flexibility thereof increases.

In this case, as shown in FIG. 10, when a film is formed on a workpiece, an adhesive substance 200 is deposited on the adhesion suppressing sheet 100, and the adhesive substance 200 is not deposited on the inner wall of the reactor. Moreover, the adhesion suppressing sheet 100 has flexibility that is higher than flexibility of the inner wall of the reactor. Therefore, according to a force applied by the adhesive substance 200 deposited on the adhesion suppressing sheet 100 to the adhesion suppressing sheet 100, the adhesion suppressing sheet 100 is easily deformed. Specifically, the adhesion suppressing sheet 100 is deformed while a curvature of a tip portion of a convex portion 101 increases as indicated by arrows in FIG. 10. Therefore, even if an amount of the adhesive substance 200 deposited on the adhesion suppressing sheet 100 increases, the internal stress of the adhesive substance 200 is less likely to increase because the adhesion suppressing sheet 100 is deformed. As a result, the internal stress of the adhesive substance 200 is suppressed from increasing to an extent that continuous adhesion is not possible with an adhesion force applied to the adhesion suppressing sheet 100 by the adhesive substance 200, and exfoliation of the adhesive substance 200 from the adhesion suppressing sheet 100 is suppressed. Therefore, it is possible to suppress flakes from being scattered in the reactor.

### SUMMARY

Meanwhile, a force applied to an adhesion suppressing sheet 100 by an adhesive substance 200 increases as an amount of the adhesive substance 200 deposited on the adhesion suppressing sheet 100 increases. Therefore, when an amount of the adhesive substance 200 deposited on the adhesion suppressing sheet 100 increases, an amount of deformation thereof increases. Specifically, in a convex portion 101 of the adhesion suppressing sheet 100, when an amount of the adhesive substance 200 deposited on the convex portion 101 increases, a curvature of a tip portion thereof increases. In this case, when a curvature of the tip portion of the convex portion 101 becomes excessive, that is, when an amount of deformation of the convex portion 101 becomes excessive, the adhesive substance 200 deposited on the convex portion 101 may be damaged due to deformation of the convex portion 101. In this case, some of the adhesive substance 200 is exfoliated from the convex portion 101, and the exfoliated adhesive substance is scattered as flakes in the reactor.

The present disclosure provides a plasma chemical vapor deposition device capable of suppressing flakes from being generated in a reactor and suppressing flakes from adhering to a workpiece placed in the reactor.

A plasma chemical vapor deposition device according to an aspect is a device configured to form a film on a workpiece placed in a reactor by converting a processing gas supplied into the reactor into plasma and decomposing the gas. In the plasma chemical vapor deposition device, an adhesion suppressing sheet suppressing the processing gas from adhering to an inner wall is arranged between a placement position of a workpiece in the reactor and the inner wall of the reactor. The adhesion suppressing sheet is a fabric that includes a plurality of first fiber bundles and a plurality of second fiber bundles. The plurality of first fiber bundles extends in a first direction and each includes a plurality of fibers, and a plurality of second fiber bundles extends in a second direction different from the first direction and each includes a plurality of fibers. Here, in the adhesion suppressing sheet, when a surface on a side of the placement position is defined as the front surface and a surface on a side of the inner wall of the reactor is defined as a rear surface, in each of the plurality of first fiber bundles, front side portions that are positioned on a front side relative to the second fiber bundles and are exposed at the front surface and rear side portions that are positioned on a rear side relative to the second fiber bundles and are not exposed at the front surface are alternately arranged in the first direction. In addition, in each of the plurality of second fiber bundles, front side portions that are positioned on a front side relative to the first fiber bundles and are exposed at the front surface and rear side portions that are positioned on a rear side relative to the first fiber bundles and are not exposed at the front surface are alternately arranged in the second direction.

According to the above configuration, when a film is formed on a workpiece in the reactor, in the first fiber bundles, a processing-gas-based adhesive substance is deposited on the front side portions, but the adhesive substance is not deposited on the rear side portions. Similarly, in the second fiber bundles, the processing-gas-based adhesive substance is deposited on the front side portions, but the adhesive substance is not deposited on the rear side portions. Therefore, in the fiber bundles, portions on which the adhesive substance is deposited and portions on which the adhesive substance is not deposited are alternately arranged in a longitudinal direction thereof. That is, in the above configuration, the adhesive substance is not deposited on the entire fiber bundles, and a plurality of regions on which the adhesive substance is deposited are positioned with intervals therebetween.

When the adhesive substance is deposited on the front side portions of the fiber bundles, the front side portions are deformed to protrude toward the placement position side according to a force applied by the adhesive substance. Due to the stress generated according to such deformation of the front side portions, the rear side portions are also deformed in addition to the front side portions in the fiber bundles. In order to deform the front side portions in this manner, because it is also necessary for the rear side portions to be deformed according to the force applied by the adhesive substance adhered to the front side portions, an amount of deformation of the front side portions is less likely to increase. Therefore, it is possible to suppress the adhesive substance deposited on the front side portions from being damaged due to an increased amount of deformation of the front side portions. Accordingly, it is possible to suppress flakes from being generated in the reactor and suppress flakes from adhering to a workpiece placed in the reactor.

Note that, when the fiber bundles have low flexibility, even if the adhesive substance is deposited on the front side portions of the fiber bundles, an amount of deformation of the front side portions is too small, and there is a risk of the internal stress of the adhesive substance increasing. Therefore, in order to suppress the adhesive substance from being exfoliated from the fiber bundles, it is necessary to deform the front side portions to some extent in order to suppress the internal stress of the adhesive substance from increasing while suppressing the front side portions on which the adhesive substance is deposited from being excessively deformed.

Incidentally, each of the fiber bundles can have a configuration in which a plurality of fibers are aligned in parallel and can have a configuration in which a plurality of fibers are twisted. However, flexibility of a fiber bundle obtained by aligning a plurality of fibers is higher than flexibility of a fiber bundle obtained by twisting a plurality of fibers. Therefore, in the above aspect, each of the plurality of first fiber bundles and the plurality of second fiber bundles may be obtained by arranging a plurality of fibers in parallel. According to this configuration, since flexibility of the fiber bundles is relatively high, an amount of deformation of the front side portions on which the adhesive substance is deposited is suppressed from becoming too small. As a result, since the internal stress of the adhesive substance deposited on the front side portions of the fiber bundles is less likely to increase, it is possible to suppress the adhesive substance from being exfoliated from the front side portion due to the increased internal stress of the adhesive substance.

In addition, in the first fiber bundles, since the stress generated in the fiber bundles according to deformation of the front side portions is dispersed in the longer rear side portions as lengths of the rear side portions in the first direction increase, deformation of the rear side portions is suppressed and deformation of the front side portions is also suppressed as a result. Similarly, in the second fiber bundles, an amount of deformation of the front side portions is further suppressed as lengths of the rear side portions in the second direction increase.

Therefore, in the aspect, at least one of the first fiber bundles and the second fiber bundles may have a width dimension that is greater than a thickness dimension, when a direction in which the plurality of fibers of the at least one of the first fiber bundles and the second fiber bundles are arranged is defined as a width direction and a direction perpendicular to both an extending direction and the width direction is defined as a thickness direction among directions perpendicular to the extending direction.

For example, when a width dimension is set to be greater than a thickness dimension in the plurality of first fiber bundles, it is possible to ensure lengths of the rear side portions of the second fiber bundles in the second direction to some extent. Therefore, excessive deformation of the front side portions of the second fiber bundles is suppressed, and accordingly, it is possible to improve an effect of suppressing the adhesive substance deposited on the front side portions from being damaged due to deformation of the front side portions.

In addition, since a width dimension is greater than a thickness dimension in the plurality of second fiber bundles, excessive deformation of the front side portions of the first fiber bundles is suppressed and it is possible to improve an effect of suppressing the adhesive substance deposited on the front side portions from being damaged.

In the aspect, each of the plurality of first fiber bundles may have a width that is 5 times a thickness or more and each of the plurality of second fiber bundles may have a width that is 5 times a thickness or more. According to this configuration, the rear side portions can be widened in both the first fiber bundles and the second fiber bundles. Therefore, it is possible to suppress excessive deformation of the front side portions on which the adhesive substance is deposited in both the first fiber bundles and the second fiber bundles.

In addition, when a film is formed on a workpiece placed at the placement position, among processing gases that are decomposed due to plasmatization, some of the gases that do not adhere to the workpiece are scattered in the reactor. Therefore, in the plasma chemical vapor deposition device of the aspect, an adhesion suppressing sheet may have a tubular shape and the adhesion suppressing sheet may be arranged to surround the placement position. According to this configuration, plasma generated in the reactor can be surrounded by the adhesion suppressing sheet. Therefore, a processing gas that does not adhere to the workpiece can easily adhere to an inner surface of the adhesion suppressing sheet, that is, the front side portions of each of the fiber bundles. Therefore, it is possible to appropriately suppress a processing gas from adhering to the inner wall of the reactor.

In the plasma chemical vapor deposition device of the aspect, the film formed on the workpiece may be a diamond-like carbon film and the fibers of the first fiber bundles and the fibers of the second fiber bundles may be carbon fibers. According to this configuration, since both the adhesive substance deposited on the front side portions of the fiber bundles and the fiber bundles are carbon-based substances, an adhesion force of the adhesive substance on the fiber bundles increases. Therefore, even if the internal stress of the adhesive substance increases, the adhesive substance is not easily exfoliated from the fiber bundles.

In the aspect, in the adhesion suppressing sheet, when a ratio of carbon atoms having a diamond structure among carbon atoms included in the diamond-like carbon film is defined as a reference ratio, a ratio of carbon atoms having a diamond structure among carbon atoms included in the carbon fibers may be equal to the reference ratio. According to this configuration, since the adhesive substance is deposited on the fiber bundles having a structure similar to the structure of the adhesive substance, it is possible to further increase an adhesion force of the adhesive substance on the fiber bundle.

In the plasma chemical vapor deposition device of the aspect, a fixing member fixed to the inner wall of the reactor is arranged between the inner wall of the reactor and the adhesion suppressing sheet, and a plurality of parts of the adhesion suppressing sheet may be bound to the fixing member by binding members. According to this configuration, since the entire adhesion suppressing sheet is not fixed to the fixing member, deformation due to deposition of the adhesive substance on the front side portions is not easily inhibited in parts other than the parts that are bound by the binding members in the adhesion suppressing sheet. In addition, since the fixing member is fixed to the inner wall of the reactor, even if the adhesion suppressing sheet is deformed according to deformation due to deposition of the adhesive substance, the fixing member is not deformed. Since the adhesion suppressing sheet is bound to the fixing member by the binding member, even if the adhesive substance is deposited and the adhesion suppressing sheet is deformed, the adhesion suppressing sheet does not easily approach the placement position side. Therefore, it is possible to suppress interference between the adhesion suppressing sheet and plasma while suppressing inhibition of deformation of the fiber bundles due to deposition of the adhesive substance.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a cross-sectional view schematically showing a part of an embodiment of a plasma chemical vapor deposition device;

FIG. 2 is a cross-sectional view schematically showing a state in which an adhesion suppressing sheet is bound in the plasma chemical vapor deposition device;

FIG. 3 is a plan view schematically showing a state in which a portion of a fiber bundle is broken in an adhesion suppressing sheet of the plasma chemical vapor deposition device;

FIG. 4 is a diagram schematically showing cross-sectional shapes of a first fiber bundle and a second fiber bundle of an adhesion suppressing sheet;

FIG. 5 is a cross-sectional view schematically showing a state in which a front side portion and a rear side portion are alternately arranged in a first fiber bundle;

FIG. 6 is a cross-sectional view schematically showing a state in which an adhesive substance is deposited on a front side portion of a first fiber bundle;

FIG. 7 is a plan view schematically showing an adhesion suppressing sheet of a plasma chemical vapor deposition device according to another embodiment;

FIG. 8 is a plan view schematically showing an adhesion suppressing sheet of a plasma chemical vapor deposition device according to another embodiment;

FIG. 9 is a plan view schematically showing an adhesion suppressing sheet of a plasma chemical vapor deposition device according to another embodiment; and

FIG. 10 is a cross-sectional view schematically showing a state in which an adhesive substance is deposited on an adhesion suppressing sheet in the related art.

### DETAILED DESCRIPTION OF EMBODIMENTS

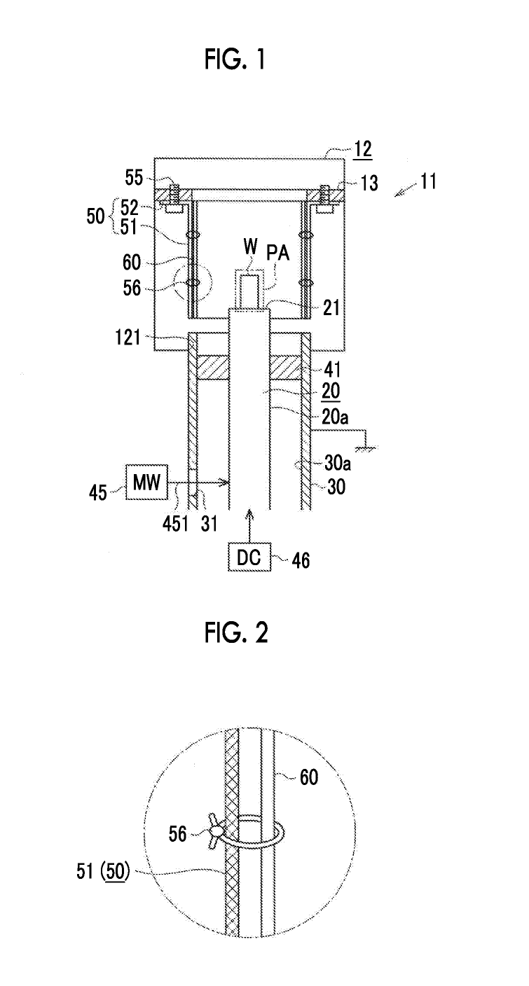

Hereinafter, an embodiment of a plasma chemical vapor deposition device will be described with reference to FIG. 1 to FIG. 6. As shown in FIG. 1, a plasma chemical vapor deposition device 11 of this embodiment includes a reactor 12 in which a workpiece W made of a conductive material such as a metal is placed. A hydrocarbon gas that is an exemplary processing gas and an inert rare gas such as argon are supplied to the vicinity of a placement position PA of the workpiece W in the reactor 12. Note that, in this specification, the plasma chemical vapor deposition device 11 is referred to as a “PCVD device 11.”

In addition, in the PCVD device 11, an elongated first conductor 20 and a tubular second conductor 30 that is positioned further outward than the first conductor 20 and that is disposed coaxially with the first conductor 20 are provided. A space is formed between an inner surface 30a of the second conductor 30 and a side surface 20a of the first conductor 20 that faces the inner surface 30a. Therefore, a sealing member 41 for regulating inflow of outside air into the reactor 12 is disposed between the second conductor 30 and the first conductor 20. An inner circumferential surface of the sealing member 41 comes in close contact with the side surface 20a of the first conductor 20 and an outer circumferential surface of the sealing member 41 comes in close contact with the inner surface 30a of the second conductor 30. Also, the sealing member 41 is made of an insulating material through which microwaves can pass.

A tip of the first conductor 20 is positioned in the reactor 12 and the workpiece W is placed thereon. That is, the tip of the first conductor 20 positioned in the reactor 12 serves as a support portion 21 that directly supports the workpiece W.

The second conductor 30 is grounded to the ground, and a potential of the second conductor 30 is “0 V.” A tip of the second conductor 30 enters the reactor 12 through an aperture 121 that is formed in a side wall of the reactor 12.

In addition, the PCVD device 11 includes a high frequency output device 45 configured to output microwaves and a DC power supply 46 configured to output a DC voltage. In the high frequency output device 45, an output unit 451 configured to output microwaves is provided. The output unit 451 passes through a through hole 31 provided in the second conductor 30, that is, is connected to the first conductor 20 without being in contact with the second conductor 30. Therefore, microwaves output from the high frequency output device 45 flow in the side surface 20a of the first conductor 20. In this case, microwaves flowing in the side surface 20a of the first conductor 20 are suppressed from leaking to the outside of the device by the second conductor 30.

In addition, the DC power supply 46 is connected to the first conductor 20 and a DC voltage from the DC power supply 46 is supplied to the first conductor 20. Therefore, a direct current flowing in the first conductor 20 also flows in the workpiece W that is supported on the first conductor 20. Accordingly, the workpiece W is charged with negative charges.

Therefore, when a film is formed on the workpiece W, microwaves are output from the high frequency output device 45 while such a direct current flows in the workpiece W. Accordingly, microwaves are propagated to a surface of the workpiece W charged with negative charges, and a hydrocarbon gas is converted into plasma and decomposed in the vicinity of the workpiece W in the reactor 12. As a result, on the surface of the workpiece W, a diamond-like carbon film (hereinafter referred to as a “DLC film”) that is a hydrocarbon-gas-based film is formed.

Next, a configuration for suppressing a hydrocarbon gas from adhering to an inner wall of the reactor 12 will be described. As shown in FIG. 1, an annular support member 13 fixed to the inner wall of the reactor 12 is provided above the placement position PA of the workpiece W in the reactor 12. The support member 13 supports a net member 50 that is an exemplary fixing member. The net member 50 is made of a metal wire. The net member 50 includes a tubular portion 51 having a cylindrical shape that surrounds the placement position PA of the workpiece W and an annular flange 52 that is connected to one end of the tubular portion 51. Therefore, the flange 52 is fastened to the support member 13 by a bolt 55. That is, the net member 50 is fixed to the inner wall of the reactor 12 through the support member 13.

In addition, a tubular adhesion suppressing sheet 60 is arranged between the tubular portion 51 of the net member 50 and the placement position PA of the workpiece W. That is, the adhesion suppressing sheet 60 is disposed to surround the placement position PA.

As shown in FIG. 2, a plurality of parts of the adhesion suppressing sheet 60 are tied up with the tubular portion 51 of the net member 50 by a plurality of binding thread materials 56 (exemplary binding members) made of carbon fibers.

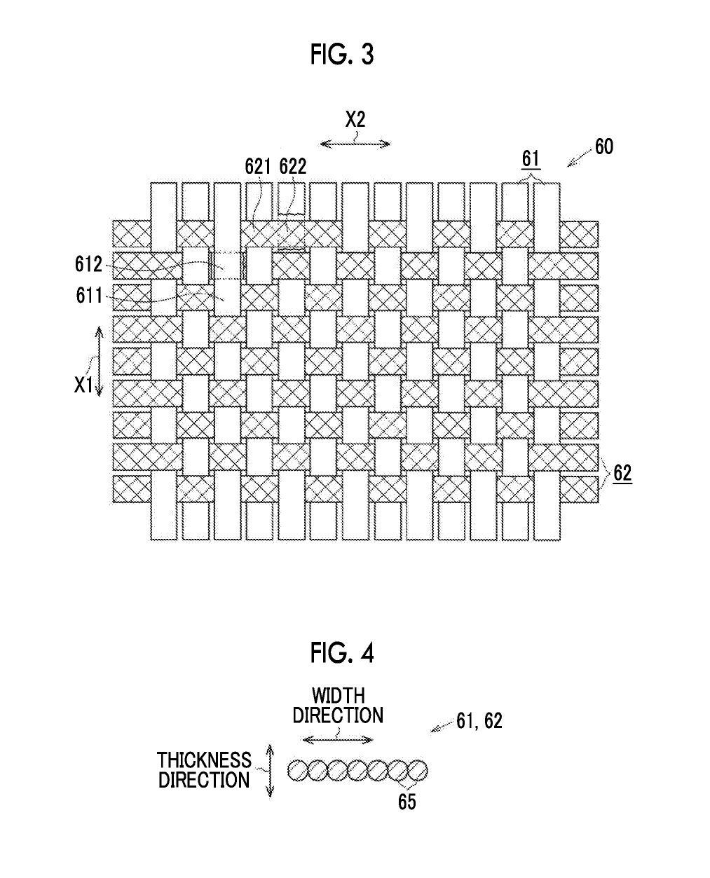

Next, a configuration of the adhesion suppressing sheet 60 will be described with reference to FIG. 3 to FIG. 5. As shown in FIG. 3, the adhesion suppressing sheet 60 is a fabric that includes a plurality of first fiber bundles 61 that extend in a first direction X1 (that is, in a vertical direction in the drawing) and a plurality of second fiber bundles 62 that extend in a second direction X2 (that is, in a horizontal direction in the drawing) that is a direction perpendicular to the first direction X1. In this embodiment, the adhesion suppressing sheet 60 is obtained by plain weaving of the first fiber bundles 61 and the second fiber bundles 62.

As shown in FIG. 4, the first fiber bundles 61 and the second fiber bundles 62 are obtained by arranging pluralities of carbon fibers 65 in parallel, that is, obtained by aligning the pluralities of carbon fibers 65. That is, in the fiber bundles 61 and 62, in the adhesion suppressing sheet 60, the pluralities of carbon fibers 65 are arranged in directions in which the pluralities of fiber bundles 61 and 62 are arranged, that is, in the same direction as the horizontal direction in FIG. 3 in the first fiber bundles 61, and in the same direction as the vertical direction in FIG. 3 in the second fiber bundles 62. In each of the fiber bundles 61 and 62, among directions perpendicular to an extending direction, a direction in which the pluralities of carbon fibers 65 of the fiber bundles 61 and 62 are arranged (that is, a horizontal direction in FIG. 4) is defined as a width direction and a direction perpendicular to both the extending direction and the width direction is defined as a thickness direction (that is, a vertical direction in FIG. 4). In this case, a width of each of the fiber bundles 61 and 62 is 5 times a thickness or more of each of the fiber bundles 61 and 62 and the widths of the first fiber bundles 61 and the widths of the second fiber bundles 62 are equal to each other.

Note that the DLC film formed on the workpiece W is a film in which carbon atoms having a diamond structure (referred to as an “sp3 structure”) and carbon atoms having a carbon structure (referred to as an “sp2 structure”) are mixed. The hardness of the DLC film increases as a ratio of carbon atoms having a diamond structure among carbon atoms included in the film increases. In addition, a composition of the adhesive substance deposited on the adhesion suppressing sheet 60 when the DLC film is formed on the workpiece W can be considered to be the same as a composition of the DLC film. Here, a ratio of carbon atoms having a diamond structure among carbon atoms included in the DLC film formed on the workpiece W is defined as a reference ratio. Therefore, in order to set a structure of the fiber bundles 61 and 62 to be similar to a structure of the adhesive substance deposited on the fiber bundles 61 and 62, as the carbon fiber 65 included in the fiber bundles 61 and 62, a carbon fiber in which a ratio of carbon atoms having a diamond structure among carbon atoms included in the carbon fiber 65 is equal to the reference ratio is used. Note that, when it is described that the ratio of carbon atoms having a diamond structure among carbon atoms is “equal,” it includes values that are the same and values considered to be the same in consideration of the hardness and the like.

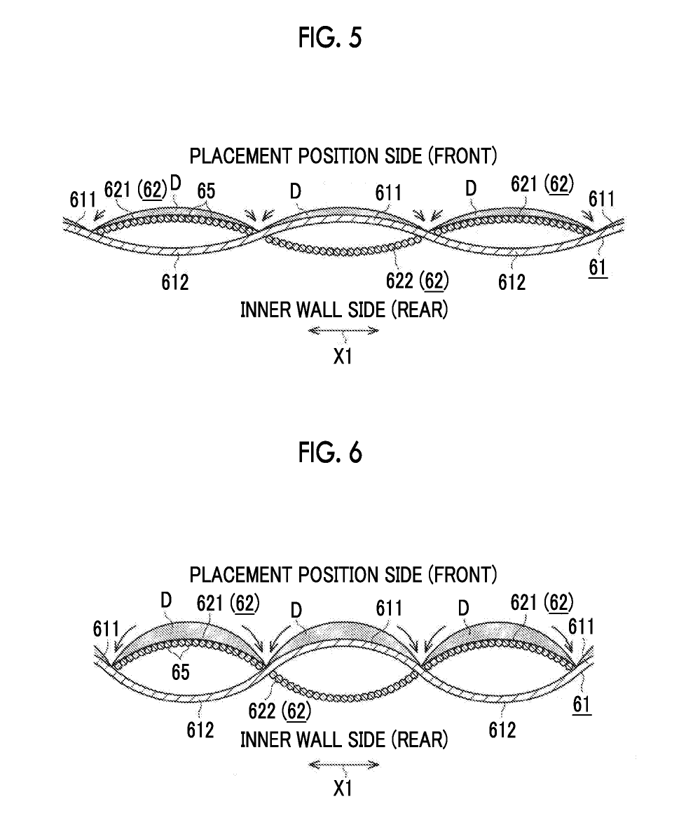

As shown in FIG. 3 and FIG. 5, in the adhesion suppressing sheet 60, when a surface of the placement position PA side is defined as a front surface and a surface of the inner wall side of the reactor 12 is defined as a rear surface, in the first fiber bundles 61, front side portions 611 that are positioned on a front side relative to the second fiber bundles 62 and are exposed at the front surface and rear side portions 612 that are positioned on a rear side relative to the second fiber bundles 62 and are not exposed at the front surface are alternately arranged in the first direction X1. Similarly, as shown in FIG. 3, in the second fiber bundles 62, front side portions 621 that are positioned on a front side relative to the first fiber bundles 61 and are exposed at the front surface and rear side portions 622 that are positioned on a rear side relative to the first fiber bundles 61 and are not exposed at the front surface are alternately arranged in the second direction X2.

Next, operations performed when the DLC film is formed on the workpiece W placed in the reactor 12 will be described with reference to FIG. 5 and FIG. 6. When a film is formed on the workpiece W, as shown in FIG. 5, among hydrocarbon gases decomposed by plasmatization, some of the gases that do not adhere to the workpiece W adhere to the front side portions 611 of the first fiber bundles 61 and the front side portions 621 of the second fiber bundles 62. Therefore, an adhesive substance D formed of the decomposed hydrocarbon gas is deposited on the front side portions 611 of the first fiber bundles 61 and the front side portions 621 of the second fiber bundles 62.

On the other hand, adhesion of a gas to the rear side portions 612 of the first fiber bundles 61 is suppressed by the second fiber bundles 62, and adhesion of a gas to the rear side portions 622 of the second fiber bundles 62 is suppressed by the first fiber bundles 61. Therefore, the adhesive substance D is not deposited on the rear side portions 612 of the first fiber bundles 61 or the rear side portions 622 of the second fiber bundles 62. That is, in this embodiment, the adhesive substance D is not deposited on the entire first fiber bundles 61 and second fiber bundles 62, but a plurality of regions on which the adhesive substance D is deposited are positioned with intervals therebetween.

When the adhesive substance D is deposited on the front side portions 611 and 621, a force is applied to the front side portions 611 and 621 by the adhesive substance D. Such a force from the adhesive substance D increases as an amount of the adhesive substance D deposited on the front side portions 611 and 621 increases. That is, as indicated by arrows in FIG. 5 and FIG. 6, a force applied to the front side portions 611 of the first fiber bundles 61 by the adhesive substance D and a force applied to the front side portions 621 of the second fiber bundles 62 by the adhesive substance D increase as an amount of the deposited adhesive substance D increases. Therefore, as shown in FIG. 6, when an amount of the adhesive substance D deposited on the front side portions 611 and 621 increases, the front side portions 611 and 621 are deformed to protrude toward the placement position PA of the workpiece W according to the force applied by the adhesive substance D. In this case, as a result of such deformation of the front side portions 611 and 621, the stress is generated in the first fiber bundles 61 and the second fiber bundles 62. Therefore, according to such stress, in the first fiber bundles 61 and the second fiber bundles 62, the rear side portions 612 and 622 are also deformed in addition to the front side portions 611 and 621.

According to the configuration and operation described above, the following effects can be obtained. (1) In the fiber bundles 61 and 62, in order to deform the front side portions 611 and 621 according to a force from the adhesive substance D deposited on the front side portions 611 and 621, it is also necessary to deform the rear side portions 612 and 622 with the force. Therefore, an amount of deformation of the front side portions 611 and 621 is less likely to increase. Accordingly, it is possible to suppress the adhesive substance D deposited on the front side portions 611 and 621 from being damaged due to an increased amount of deformation of the front side portions 611 and 621. Therefore, it is possible to suppress flakes from being generated in the reactor 12 and suppress flakes from adhering to the workpiece W placed in the reactor 12.

(2) In this embodiment, since the fiber bundles 61 and 62 are obtained by aligning the plurality of carbon fibers 65, the fiber bundles have higher flexibility than fiber bundles of yarns obtained by twisting a plurality of carbon fibers. Therefore, an amount of deformation of the front side portions 611 and 621 on which the adhesive substance D is deposited is suppressed from becoming too small, and the internal stress of the adhesive substance D deposited on the front side portions 611 and 621 is less likely to increase. Therefore, it is possible to suppress the adhesive substance D from being exfoliated from the front side portions 611 and 621 due to the increased internal stress of the adhesive substance D.

(3) In addition, since the width of each of the first fiber bundles 61 and the second fiber bundles 62 is 5 times the thickness or more, it is possible to sufficiently ensure lengths of the rear side portions 622 of the second fiber bundles 62 in the second direction X2, and it is possible to sufficiently ensure lengths of the rear side portions 612 of the first fiber bundles 61 in the first direction X1. Therefore, the stress generated in the fiber bundles 61 and 62 according to deformation of the front side portions 611 and 621 is dispersed in the long rear side portions 612 and 622. As a result, deformation of the rear side portions 612 and 622 is suppressed, and deformation of the front side portions 611 and 621 is also suppressed as a result. Therefore, excessive deformation of the front side portions 611 and 621 of the fiber bundles 61 and 62 is suppressed, and accordingly, it is possible to further improve an effect of suppressing the adhesive substance D deposited on the front side portions 611 and 621 from being damaged due to deformation of the front side portions 611 and 621.

(4) When widths of any one group of the first fiber bundles 61 and the second fiber bundles 62 are narrower than widths of the other fiber bundles, lengths of the rear side portions of the other fiber bundles in an extending direction are short, and the stress generated in the other fiber bundles due to deformation of the front side portions is not easily dispersed in the rear side portions. On the other hand, in this case, since lengths of the rear side portions of the one group of the fiber bundles in the extending direction are long, the stress generated in the one group of the fiber bundles due to deformation of the front side portions is easily dispersed in the rear side portions. Therefore, while the front side portions of the one group of the fiber bundles are not deformed much, an amount of deformation of the front side portions of the other fiber bundles may be excessive. In this case, since the amount of deformation of the front side portions of the other fiber bundles is excessive, it is necessary to replace the adhesion suppressing sheet 60 even if the adhesive substance D is not yet exfoliated from the one group of the fiber bundles. In this regard, in this embodiment, since widths of the first fiber bundles 61 and widths of the second fiber bundles 62 are equal to each other, it is possible to suppress a replacement frequency of the adhesion suppressing sheet 60 from increasing due to small widths of one of the groups of fiber bundles.

(5) Since the tubular adhesion suppressing sheet 60 is arranged to surround the placement position PA of the workpiece W, plasma generated in the reactor 12 can be surrounded by the adhesion suppressing sheet 60. Therefore, a processing gas that does not adhere to the workpiece W can easily adhere to an inner surface of the adhesion suppressing sheet 60, that is, the front side portions 611 and 621 of the fiber bundles 61 and 62. Therefore, it is possible to appropriately suppress a processing gas from adhering to the inner wall of the reactor 12.

(6) Since both the adhesive substance D deposited on the front side portions 611 and 621 of the fiber bundles 61 and 62 and the fiber bundles 61 and 62 are carbon-based substances, an adhesion force of the adhesive substance D on the fiber bundles 61 and 62 increases. Therefore, even if the internal stress of the adhesive substance D increases, the adhesive substance D is not easily exfoliated from the fiber bundles 61 and 62.

(7) A ratio of carbon atoms having a diamond structure among carbon atoms included in the carbon fiber 65 of the fiber bundles 61 and 62 is equal to the reference ratio. Therefore, the adhesive substance D is deposited on the fiber bundles 61 and 62 having a structure similar to the structure of the adhesive substance D. Therefore, it is possible to further increase an adhesion force of the adhesive substance D on the fiber bundles 61 and 62. In addition, since the structure of the adhesive substance D is similar to the structure of the adhesion suppressing sheet 60, a coefficient of thermal expansion of the adhesive substance D is substantially equal to a coefficient of thermal expansion of the adhesion suppressing sheet 60. Accordingly, when heat is applied to the adhesion suppressing sheet 60 and the adhesion suppressing sheet 60 and the adhesive substance D thermally expand, an amount of thermal expansion of the adhesive substance D becomes substantially equal to an amount of thermal expansion of the adhesion suppressing sheet 60. Therefore, it is possible to suppress the adhesive substance D from being exfoliated from the adhesion suppressing sheet 60 even if the adhesion suppressing sheet 60 thermally expands.

(8) A plurality of parts of the adhesion suppressing sheet 60 are bound to the net member 50 fixed to the inner wall of the reactor 12 by the binding thread material 56. Therefore, deformation of the fiber bundles 61 and 62 due to deposition of the adhesive substance D on the front side portions 611 and 621 is not easily inhibited in parts other than the parts that are bound by the binding thread material 56 in the adhesion suppressing sheet 60. Further, even if the fiber bundles 61 and 62 are deformed due to deposition of the adhesive substance D, since the net member 50 fixed to the inner wall of the reactor 12 is not deformed, the adhesion suppressing sheet 60 does not easily approach the placement position PA. Therefore, it is possible to suppress interference between the adhesion suppressing sheet 60 and plasma while suppressing inhibition of deformation of the fiber bundles 61 and 62 due to deposition of the adhesive substance D.

(9) In addition, since the adhesion suppressing sheet 60 is attached to the net member 50 by the plurality of binding thread materials 56, when the bolt 55 is removed to release the net member 50 fixed to the inner wall of the reactor 12, it is possible to easily detach the adhesion suppressing sheet 60 from the inside of the reactor 12 together with the net member 50. Therefore, compared to when the adhesion suppressing sheet 60 is directly attached to the inner wall of the reactor 12 by the plurality of binding thread materials 56, the adhesion suppressing sheet 60 can be easily replaced.

(10) In addition, even if the adhesive substance D is deposited in this manner, since it is possible to suppress the adhesion suppressing sheet 60 from approaching the placement position PA, it is not necessary to dispose the adhesion suppressing sheet 60 far apart from the placement position PA in order to suppress interference between the adhesion suppressing sheet 60 and plasma, and a small reactor can be used as the reactor 12. That is, it is possible to reduce the size of the PCVD device 11.

Also, the embodiment may be changed to other embodiments to be described below. As a fixing member to which the adhesion suppressing sheet 60 is bound by the binding thread material 56, a member other than the net member 50 may be used as long as it has sufficient rigidity that deformation does not occur even if a force based on deformation of the fiber bundles 61 and 62 due to deposition of the adhesive substance D is applied by the adhesion suppressing sheet 60. For example, a cylindrical body formed of a plate of a metal such as aluminum can be used as the fixing member.

The adhesion suppressing sheet 60 may be directly attached to the inner wall of the reactor 12 without the fixing member. The fiber bundles 61 and 62 may include a carbon fiber whose ratio of carbon atoms having a diamond structure is different from the reference ratio. In this case also, it is possible to obtain the same effects as in (1) to (6) and (8) to (10). Also, in order to suppress exfoliation of the adhesive substance D, it is desirable that a ratio of carbon atoms having a diamond structure in the fiber bundles 61 and 62 be as close to the reference ratio as possible.

The fiber bundles 61 and 62 may include fibers other than the carbon fibers as long as they are deformed by a force from the deposited adhesive substance D. In this case also, it is possible to obtain the same effects as in (1) to (5) and (8) to (10).

The adhesion suppressing sheet may not have a tubular shape. In this case also, when a plurality of adhesion suppressing sheets are disposed to surround the placement position PA, it is possible to suppress the adhesive substance D from being deposited on the inner wall of the reactor 12.

Fiber bundles other than the fiber bundles obtained by arranging pluralities of fibers in parallel may be used as long as they are deformed by a force from the deposited adhesive substance D. As an example of such fiber bundles, a yarn obtained by twisting pluralities of fibers can be used.

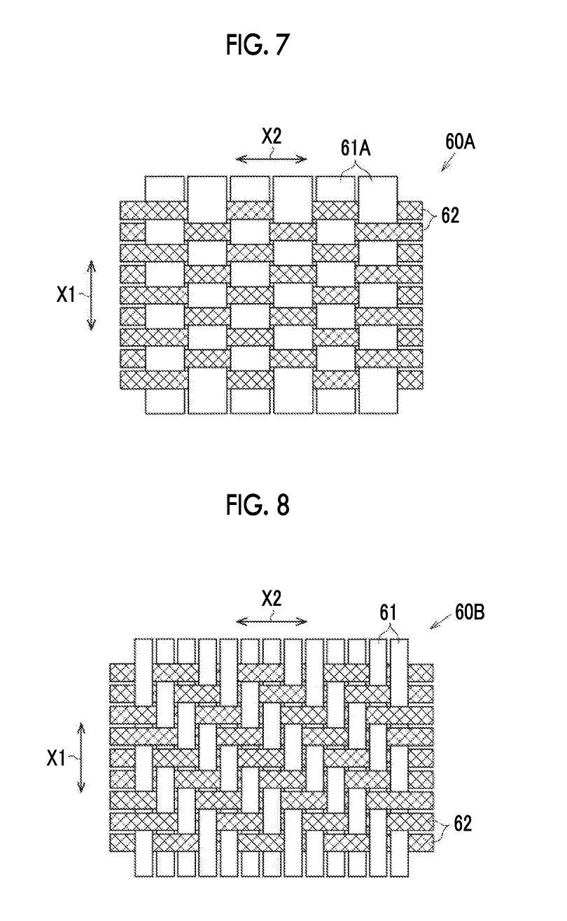

In the embodiment, the adhesion suppressing sheet 60 is obtained by plain weaving of the first fiber bundles 61 and the second fiber bundles 62 whose widths are the same. However, for example, as shown in FIG. 7, an adhesion suppressing sheet 60A may be obtained by plain weaving of the second fiber bundles 62 and first fiber bundles 61A whose widths are wider than widths of the second fiber bundles 62. When the adhesion suppressing sheet 60A is provided in the reactor 12, it is possible to obtain the same effects as in (1) to (3) and (5) to (10).

In addition, on the contrary to FIG. 7, the adhesion suppressing sheet may be obtained by plain weaving of the first fiber bundles 61 and the second fiber bundles whose widths are wider than widths of the first fiber bundles 61. An adhesion suppressing sheet may be a fabric obtained by performing weaving other than plain weaving as long as the fabric includes a plurality of first fiber bundles and a plurality of second fiber bundles, and front side portions and rear side portions are alternately arranged in extending directions of the fiber bundles. For example, as shown in FIG. 8, an adhesion suppressing sheet 60B may be obtained by twilling the first fiber bundles 61 and the second fiber bundles 62. When the adhesion suppressing sheet 60B is provided in the reactor 12, it is possible to obtain the same effects as in the embodiment.

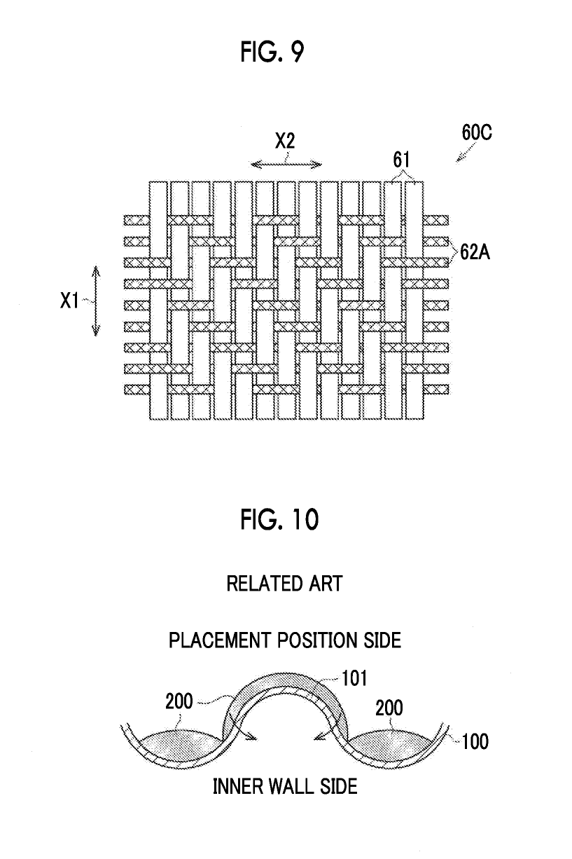

In addition, as shown in FIG. 9, the adhesion suppressing sheet may be obtained by twilling fiber bundles whose widths are different from each other. For example, an adhesion suppressing sheet 60C may be obtained by twilling the first fiber bundles 61 and second fiber bundles 62A whose widths are narrower than widths of the first fiber bundles 61. When the adhesion suppressing sheet 60C is provided in the reactor 12, it is possible to obtain the same effects as in (1) to (3) and (5) to (10).

The widths of the fiber bundles 61 and 62 may be less than 5 times the thicknesses of the fiber bundles 61 and 62 as long as the adhesive substance D is not exfoliated from the front side portions 611 and 621 due to deformation of the front side portions 611 and 621 according to a force from the adhesive substance D deposited on the front side portions 611 and 621.

In the embodiment, the adhesion suppressing sheet 60 may include the first fiber bundles 61 and the second fiber bundles 62 that extend in directions perpendicular to each other. However, as long as the front side portions 611 and the rear side portions 612 are alternately arranged in the first fiber bundles 61, and the front side portions 621 and the rear side portions 622 are alternately arranged in the second fiber bundles 62, an adhesion suppressing sheet including weaves of the first fiber bundles 61 and the second fiber bundles 62 that form an angle that is not a right angle may be placed in the reactor 12.

The PCVD device 11 in which the adhesion suppressing sheet 60 is placed in the reactor 12 may be embodied as a device configured to form a film other than the DLC film on the workpiece W.

What is claimed is:

1. A plasma chemical vapor deposition device configured to form a film on a workpiece placed in a reactor by converting a processing gas supplied into the reactor into plasma and decomposing the gas, comprising,
an adhesion suppressing sheet suppressing the processing gas from adhering to an inner wall of the reactor, wherein
the adhesion suppressing sheet is arranged between a placement position of the workpiece in the reactor and the inner wall of the reactor,
the adhesion suppressing sheet is a fabric that includes a plurality of first fiber bundles and a plurality of second fiber bundles, the plurality of first fiber bundles extending in a first direction and each including a plurality of fibers, and the plurality of second fiber bundles extending in a second direction different from the first direction and each including a plurality of fibers, and
in the adhesion suppressing sheet, when a surface on a side of the placement position is defined as a front surface and a surface on a side of the inner wall of the reactor is defined as a rear surface,
in each of the plurality of first fiber bundles, front side portions that are positioned on a front side relative to the second fiber bundles and are exposed at the front surface, and rear side portions that are positioned on a rear side relative to the second fiber bundles and are not exposed at the front surface are alternately arranged in the first direction, and
in each of the plurality of second fiber bundles, front side portions that are positioned on a front side relative to the first fiber bundles and are exposed at the front surface, and rear side portions that are positioned on a rear side relative to the first fiber bundles and are not exposed at the front surface are alternately arranged in the second direction.

2. The plasma chemical vapor deposition device according to claim 1, wherein
each of the plurality of first fiber bundles and the plurality of second fiber bundles is obtained by arranging a plurality of fibers in parallel.

3. The plasma chemical vapor deposition device according to claim 1, wherein
at least one of the first fiber bundles and the second fiber bundles has a width dimension that is greater than a thickness dimension, when a direction in which the plurality of fibers of the at least one of the first fiber bundles and the second fiber bundles are arranged is defined as a width direction and a direction perpendicular to both an extending direction and the width direction is defined as a thickness direction among directions perpendicular to the extending direction.

4. The plasma chemical vapor deposition device according to claim 3, wherein
each of the plurality of first fiber bundles has a width that is 5 times a thickness or more and each of the plurality of second fiber bundles has a width that is 5 times a thickness or more.

5. The plasma chemical vapor deposition device according to claim 1, wherein
the adhesion suppressing sheet has a tubular shape, and the adhesion suppressing sheet is arranged to surround the placement position.

6. The plasma chemical vapor deposition device according to claim 1, wherein
the film formed on the workpiece is a diamond-like carbon film and the fibers of the first fiber bundles and the fibers of the second fiber bundles are carbon fibers.

7. The plasma chemical vapor deposition device according to claim 6, wherein
in the adhesion suppressing sheet, when a ratio of carbon atoms having a diamond structure among carbon atoms included in the diamond-like carbon film is defined as a reference ratio, a ratio of carbon atoms having a diamond structure among carbon atoms included in the carbon fibers is equal to the reference ratio.

8. The plasma chemical vapor deposition device according to claim 1, wherein
a fixing member fixed to the inner wall of the reactor is arranged between the inner wall of the reactor and the adhesion suppressing sheet, and a plurality of parts of the adhesion suppressing sheet are bound to the fixing member by binding members.
